(19) United States
(12) Patent Application Publication
(10) Pub. No.: US 2026/0140185 A1
(43) Pub. Date: May 21, 2026

(54) CHARGE/DISCHARGE INSPECTION SYSTEM

(71) Applicant: NIPPON STEEL TEXENG. CO., LTD., Tokyo (JP)

(72) Inventor: Tomoki HARAGUCHI, Tokyo (JP)

(21) Appl. No.: 19/451,773

(22) Filed: Jan. 16, 2026

Related U.S. Application Data
(63) Continuation of application No. PCT/JP2023/026532, filed on Jul. 20, 2023.

(51) Int. Cl. G01R 31/36; H01M 10/42

(52) U.S. Cl. CPC G01R 31/3644; H01M 10/4285

(57) ABSTRACT

There is provided a charge/discharge inspection system that enables easy maintenance such as cleaning the tips of probes or replacing defective probes without a complex configuration. The charge/discharge inspection system includes: a battery inspection unit of a charge/discharge inspection apparatus; a tray that is capable of containing a probe unit, a charge/discharge power supply unit, and a charge/discharge power supply-integrated probe unit in a storage part, is conveyed with one of them contained in the tray, and is placed in the battery inspection unit; and a conveying apparatus that conveys the tray from the battery inspection unit to another location, or conveys the tray from another location to the battery inspection unit.

### CROSS-REFERENCE TO RELATED APPLICATIONS

This application is a Continuation Application of PCT International Application No. PCT/JP2023/026532, filed on Jul. 20, 2023, the disclosure of which is hereby incorporated by reference herein in their entireties.

### TECHNICAL FIELD

The present invention relates to a charge/discharge inspection system having a tray capable of conveying a probe unit and the like.

### BACKGROUND ART

Due to low voltage of the smallest battery unit (a single cell) that constitutes a secondary battery, secondary batteries are often used by packing cells with similar characteristics. Therefore, apparatuses that manufacture such secondary batteries also require precision and environment for manufacturing cells with similar characteristics.

Further, charge/discharge inspection systems that test secondary batteries thus also require measurement with high precision, and require maintenance such as cleaning the tips of probes and replacing defective probes to avoid contact failure.

However, the work of attaching/detaching or replacing a probe unit of a charge/discharge inspection system for maintenance is often done manually. Further, stacking a large number of battery inspection units for charge/discharge inspection leads to working in high places. Note that the increase in the size of secondary batteries due to the increase in their capacity also increases the size and weight of the apparatus.

Thus, the maintenance of a probe unit separately requires facilities or special jigs for ensuring the safety of the operators.

Techniques related to cleaning probes or replacing a probe unit based on such a background include, for example, the techniques described in Patent Literature 1 and Patent Literature 2.

Patent Literature 1 describes a probe cleaning apparatus for improving the efficiency of the work of cleaning probes of a charge/discharge inspection apparatus. More specifically, Patent Literature 1 describes carrying, in a charge/discharge inspection apparatus 2, a probe cleaning apparatus 1 including a cleaning brush that faces probes 211 and 221 of the charge/discharge inspection apparatus 2 and a driving mechanism 15 that drives the cleaning brush, and driving the cleaning brush via the driving mechanism 15, thereby cleaning adhered substances on the tips of the probes 211 and 221 without manual operation (see paragraph 0031 of the specification and FIG. 1).

On the other hand, Patent Literature 2 describes a charge/discharge inspection system and an attaching/detaching unit for reducing the load on a conveying apparatus in replacing a probe unit. More specifically, Patent Literature 2 describes that the charge/discharge inspection system includes a charge/discharge inspection apparatus for charging/discharging secondary batteries for inspection, a conveying apparatus that conveys secondary batteries to the charge/discharge inspection apparatus, and an attaching/detaching unit 80 that attaches/detaches a probe unit 46. Further, Patent Literature 2 describes that the attaching/detaching unit 80 includes a moving mechanism 84 that moves the probe unit 46 to attach/detach it to/from an inspection unit, and reaction force transmission means that transmits reaction force generated during attachment/detachment to a receiving part of the inspection unit (see Abstract and FIG. 4).

### Citation List

### Patent Literature

Patent Literature 1: Japanese Patent No. 6055806
Patent Literature 2: Japanese Patent No. 6144074

### SUMMARY OF INVENTION

### Technical Problem

However, when the probe cleaning apparatus described in Patent Literature 1 is used for cleaning in a battery inspection unit, the wind generated by the driving of the cleaning brush may scatter fine foreign substances, which can cause contact failure, short-circuit accidents, or the like.

Further, the charge/discharge inspection system described in Patent Literature 2 requires a separate mechanism (the attaching/detaching unit) for inserting/removing the probe unit, and the attaching/detaching unit is mounted on the conveying apparatus, which can make the conveying apparatus more complex or heavier.

Therefore, the present invention aims to provide a charge/discharge inspection system that enables easy maintenance such as cleaning the tips of probes or replacing defective probes without a complex configuration.

### Solution to Problem

A charge/discharge inspection system according to the present invention includes:
a battery inspection unit of a charge/discharge inspection apparatus;
a tray that is capable of containing a probe unit, a charge/discharge power supply unit, and a charge/discharge power supply-integrated probe unit in a storage part, is conveyed with one of the probe unit, the charge/discharge power supply unit, and the charge/discharge power supply-integrated probe unit contained in the tray, and is placed in the battery inspection unit; and
a conveying apparatus that conveys the tray from the battery inspection unit to another location, or conveys the tray from another location to the battery inspection unit.

Thus, the probe unit, the charge/discharge power supply unit, or the charge/discharge power supply-integrated probe unit is contained in the tray and conveyed by the conveying apparatus together with the tray, thereby allowing conveyance of them from the battery inspection unit to another location or from another location to the battery inspection unit.

Further, the tray desirably includes: a plurality of tray separators that separate a storage area in the storage part; and a guide part that supports the probe unit or the charge/discharge power supply-integrated probe unit contained in the storage part so that a probe of the probe unit or the charge/discharge power supply-integrated probe unit does not contact with an inside of the storage part.

Note that desirably, the storage part is capable of further containing a secondary battery to be inspected, and the tray is conveyed with the secondary battery to be inspected contained in the tray, and is placed in the battery inspection unit.

The storage part is desirably capable of further containing a lift capable of lifting or lowering the probe unit, the charge/discharge power supply unit, or the charge/discharge power supply-integrated probe unit.

Further, in the charge/discharge inspection system, the tray desirably includes a tray-side fixing mechanism for fixing, to the tray, the probe unit, the charge/discharge power supply unit, or the charge/discharge power supply-integrated probe unit contained in the storage part of the tray when the tray is conveyed by the conveying apparatus, when the tray rises or lowers while being placed on a lifting plate of the battery inspection unit, or when the probe unit, the charge/discharge power supply unit, or the charge/discharge power supply-integrated probe unit is contained in the tray.

Furthermore, in the charge/discharge inspection system, the battery inspection unit desirably includes a battery inspection unit-side fixing mechanism for fixing, in the battery inspection unit, the probe unit, the charge/discharge power supply unit, or the charge/discharge power supply-integrated probe unit that is conveyed while being contained in the tray.

In addition, the charge/discharge inspection system desirably further includes:
a lifting mechanism that lifts the tray placed on a lifting plate of the battery inspection unit, and connects the probe unit, the charge/discharge power supply unit, or the charge/discharge power supply-integrated probe unit contained in the tray and a connecting part provided on the battery inspection unit side to each other; or
a lifting mechanism that lowers a hanging plate of the battery inspection unit, and connects the probe unit, the charge/discharge power supply unit, or the charge/discharge power supply-integrated probe unit contained in the tray placed in the battery inspection unit and the connecting part provided on the battery inspection unit side to each other.

### Advantageous Effects of Invention

With such a configuration of the charge/discharge inspection system according to the present invention, the whole tray is conveyed by the conveying apparatus with the probe unit or the like contained in the tray, thereby allowing conveyance of them from the battery inspection unit to another location or from another location to the battery inspection unit, thus enabling easy maintenance such as cleaning or replacement of probes of the probe unit or the like, which has been removed and conveyed, without requiring a complex configuration such as an attaching/detaching unit mechanism.

### BRIEF DESCRIPTION OF DRAWINGS

FIG. 1 is a diagram illustrating a tray according to an embodiment of the present invention, (A) is a schematic front view, (B) is a partially-omitted cross-sectional view along the line A-A in (A), and (C) is a partially-omitted cross-sectional view along the line B-B in (B).

FIG. 2 is a diagram illustrating a state in which the tray according to the embodiment of the present invention contains a probe unit, (A) is a partially-omitted cross-sectional view in that state along the line B-B as in (C) of FIG. 1, and (B) is a partially-omitted cross-sectional view in that state along the line A-A as in (B) of FIG. 1.

FIG. 3 is a diagram illustrating a state in which the tray according to the embodiment of the present invention contains a charge/discharge power supply-integrated probe unit, (A) is a partially-omitted cross-sectional view in that state along the line B-B as in (C) of FIG. 1, and (B) is a partially-omitted cross-sectional view in that state along the line A-A as in (B) of FIG. 1.

FIG. 4 is a diagram illustrating a state in which the tray according to the embodiment of the present invention contains secondary batteries, (A) is a partially-omitted cross-sectional view in that state along the line B-B as in (C) of FIG. 1, and (B) is a partially-omitted cross-sectional view in that state along the line A-A as in (B) of FIG. 1.

FIG. 5 is a diagram illustrating a flow in which the tray according to the embodiment of the present invention conveys the probe unit to a battery inspection unit.

FIG. 6 is a diagram illustrating a flow in which the tray according to the embodiment of the present invention conveys the charge/discharge power supply-integrated probe unit to the battery inspection unit.

FIG. 7 is a diagram illustrating an example of a tray-side fixing mechanism according to the embodiment of the present invention, (A) is a diagram showing the locked state, and (B) is a diagram showing the unlocked state.

FIG. 8 is a diagram illustrating an example of a battery inspection unit-side fixing mechanism according to the embodiment of the present invention, (A) is a diagram showing the locked state, and (B) is a diagram showing the unlocked state.

FIG. 9 is a diagram illustrating an example of a tray-side fixing mechanism and a battery inspection unit-side fixing mechanism according to another embodiment of the present invention.

FIG. 10 is a diagram illustrating an example of a tray-side fixing mechanism and a battery inspection unit-side fixing mechanism according to another embodiment of the present invention.

FIG. 11 is a diagram illustrating an example of a maintenance station according to an embodiment of the present invention.

### DESCRIPTION OF EMBODIMENTS

Embodiments of the present invention will be described below in detail, but the description of the constituent features described below shows examples (representative examples) of embodiments of the present invention, and the present invention is not limited to the following content unless the spirit thereof is changed. Further, this description will omit the detailed description of the already described components by giving the same reference numerals thereto in the drawings.

### Charge/Discharge Inspection System

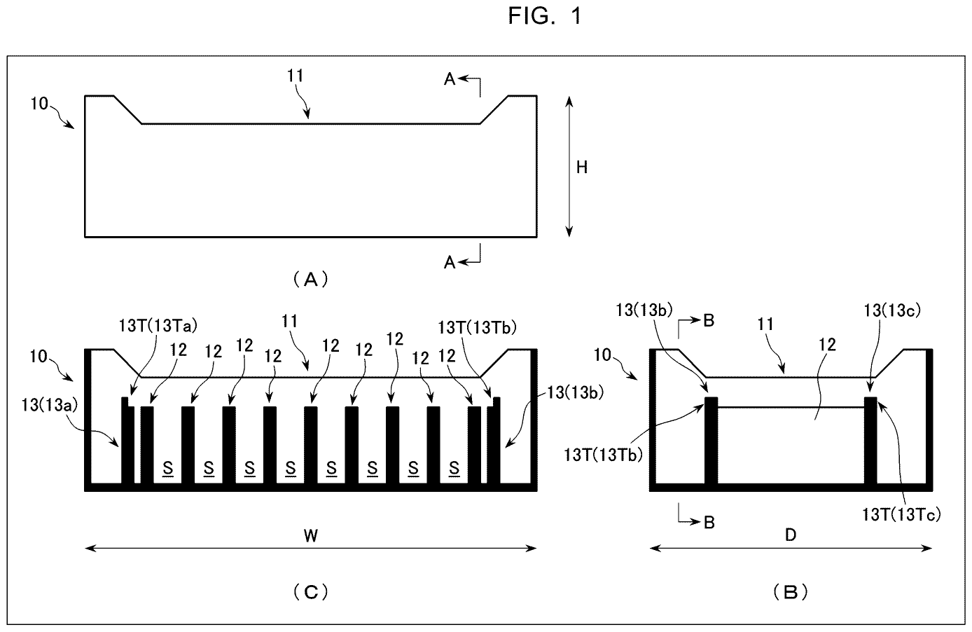

A charge/discharge inspection system according to an embodiment of the present invention includes a battery inspection unit of a charge/discharge inspection apparatus, a tray 10 (see FIG. 1), a conveying apparatus, and a maintenance station.

### Battery Inspection Unit

The charge/discharge inspection apparatus is an apparatus that performs charge/discharge inspection of secondary batteries. The charge/discharge inspection apparatus includes a battery inspection unit having a power supply (a charge/discharge power supply unit) and a connecting part described later. Further, the charge/discharge inspection apparatus includes, for example, a probe unit having probes for feeding power from the power supply (the charge/discharge power supply unit) to secondary batteries to be inspected or a charge/discharge power supply-integrated probe unit in which a charge/discharge power supply is integrated with a probe unit.

### Tray

The tray 10 in this embodiment has a square shape with a height H of 150 mm, a depth D of 200 mm, and a width W of 450 mm (see FIG. 1), but the shape and size of the tray are not limited thereto.

Further, the tray 10 has a recessed area (a storage part 11) in the center, and the storage part 11 can contain the probe unit, the charge/discharge power supply unit, the charge/discharge power supply-integrated probe unit, or the like. The design of the storage part 11 such as its shape or size can be modified appropriately according to the probe unit to be contained or the like.

Note that the tray 10 includes a plurality of tray separators 12 that separate the storage area in the storage part 11 and guide parts 13 that support the probe unit or the charge/discharge power supply-integrated probe unit placed in the storage part 11. In this embodiment, nine plate-shaped tray separators 12 are arranged in the tray 10 at equal intervals, and the storage part 11 is separated into eight spaces S (see FIG. 1(C)).

Further, this embodiment includes four pillar-shaped guide parts 13 (13a, 13b, 13c, and the remaining one, which is not shown) near the outer frame of the tray 10. The top 13T of each of the guide parts 13 has a recess, and a probe holding plate of the probe unit or the like engages with this recess, thereby supporting the probe unit or the like and also positioning the probe unit or the like contained in the storage part 11.

Note that the guide parts 13 are for supporting the probe unit or the charge/discharge power supply-integrated probe unit so that the probes of them do not contact with the storage part 11, and this embodiment is configured so that the top 13T of each of the four guide parts 13 engages with its corresponding part of the probe unit or the like to ensure stable support and positioning, but as long as this can be achieved, the shape and number of the guide parts, the positions where they are provided, and the like are not limited.

Furthermore, making the height of the tray separators 12 equal to the height of the recesses of the tops 13T of the guide parts 13 allows the guide parts 13 and the tray separators 12 to support the probe unit or the like.

### Probe Unit

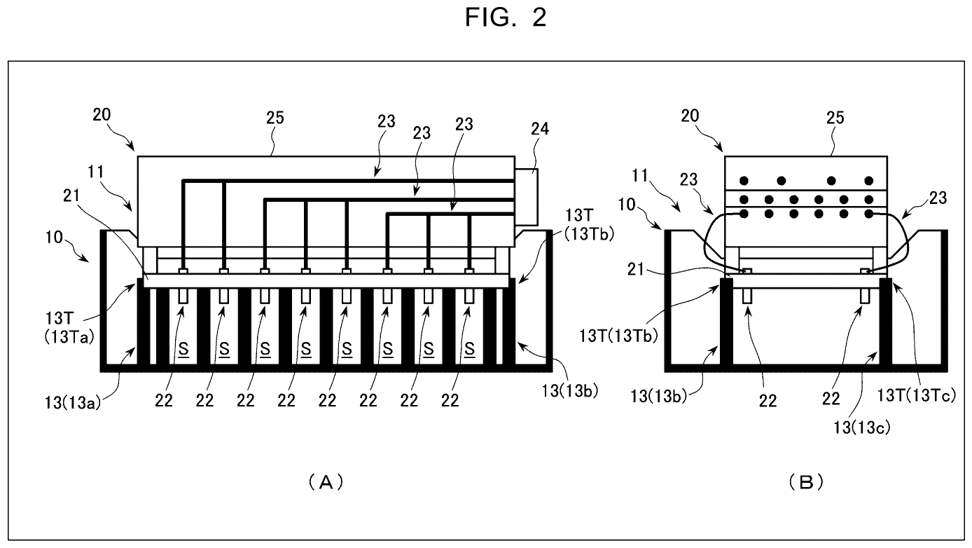

FIG. 2 is a diagram illustrating the state in which the tray 10 contains a probe unit 20.

The probe unit 20 includes a probe holding plate 21, probes 22, wires 23, a connecting part 24, and an electrical component storage 25. In this embodiment, the probe unit 20 has eight probes 22 held by the probe holding plate 23.

Specifically, the probe unit 20 is contained in the storage part 11 with the probe holding plate 21 supported by the guide parts 13 (13T) or the like. Further, the probes 22 of the probe unit 20 are contained in their corresponding spaces S so as not to contact with the storage part 11 (see FIG. 2(A)).

### Charge/Discharge Power Supply-Integrated Probe Unit

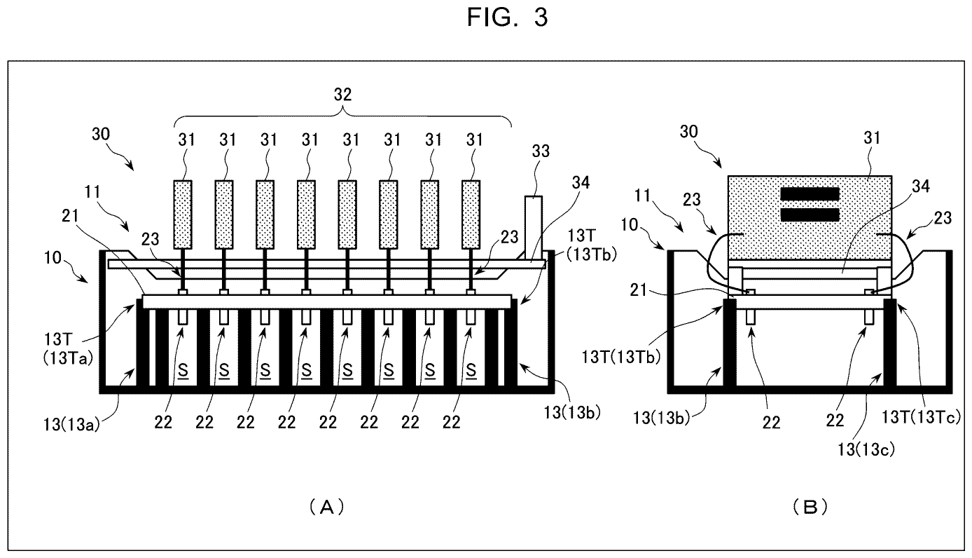

On the other hand, FIG. 3 is a diagram illustrating the state in which the tray 10 contains a charge/discharge power supply-integrated probe unit 30.

The charge/discharge power supply-integrated probe unit 30 has a charge/discharge power supply unit 32 having a probe holding plate 21, probes 22, wires 23, and a plurality of power supplies 31, and a connecting part 33. The connecting part 33 of the charge/discharge power supply-integrated probe unit 30 includes a power feeder (a DC power feeder) and a communication part for transmitting/receiving input/output signals and the like. Note that FIG. 3 partially omits the depiction of the casing (the outer frame) 34 of the charge/discharge power supply-integrated probe unit 30, and the casing 34 is not particularly limited as long as it has a shape that can be contained in the tray 10 and has a shape that can be connected to the battery inspection unit.

In this embodiment, the charge/discharge power supply-integrated probe unit 30 has eight probes 22 held by the probe holding plate 23, as in the case of the probe unit 20. Note that the charge/discharge power supply unit 32 includes eight power supplies 31, and the power supplies 31 are connected to their corresponding probes 22 via the wires 23. Further, the charge/discharge power supply unit 32 has the power supplies 31 integrated with a single board (a base board) by being connected thereto via connectors, and is further unitized by a casing that contains them.

Therefore, the charge/discharge power supply-integrated probe unit 30 is also contained in the storage part 11 with the probe holding plate 21 supported by the guide parts 13 (13T) or the like, and the probes 22 of the charge/discharge power supply-integrated probe unit 30 are contained in their corresponding spaces S so as not to contact with the storage part 11 (see FIG. 3(A)).

### Secondary Battery

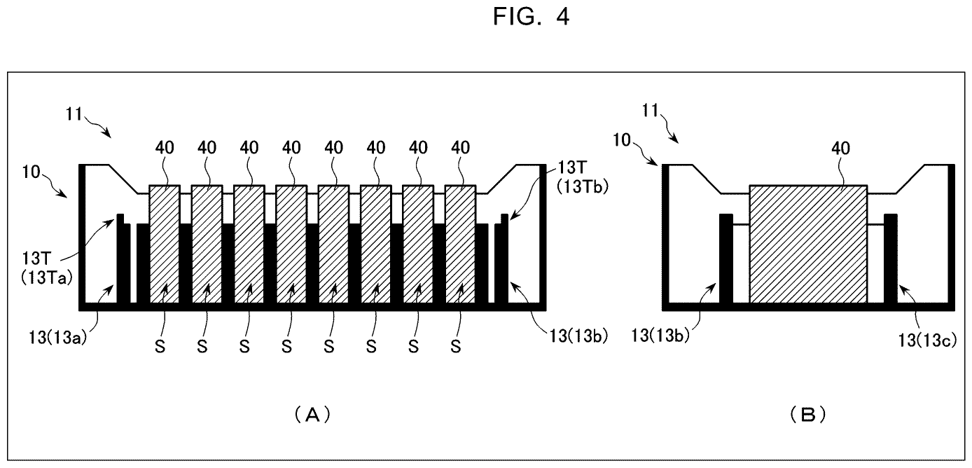

Furthermore, FIG. 4 is a diagram illustrating the state in which the tray 10 contains secondary batteries 40.

Since the tray 10 includes a plurality of tray separators 12 as mentioned above, the storage part 11 is separated into a plurality of spaces S (see FIG. 1 (C)). Therefore, the tray 10 can contain the secondary batteries 40 to be inspected in their corresponding spaces S.

### Charge/Discharge Power Supply Unit

In addition, although not shown, the tray 10 can also contain the charge/discharge power supply unit 32 in the storage part 11. In this case, the wires 23 are disconnected from their corresponding power supplies 31, and the charge/discharge power supply unit 32 is contained in the storage part 11 with its casing supported by the guide parts 13 of the tray 10.

Thus, the tray 10 can contain the probe unit, the charge/discharge power supply unit, the charge/discharge power supply-integrated probe unit, and secondary batteries to be inspected, and they are conveyed by the conveying apparatus together with the tray 10 as described below, thereby allowing conveyance of them from the battery inspection unit to another location or from another location to the battery inspection unit.

### Lift

Note that the tray 10 can also contain a lift (not shown) in the storage part 11. The lift is capable of lifting or lowering the probe unit, the charge/discharge power supply unit, the charge/discharge power supply-integrated probe unit, and the like, and, for example, an electric actuator available from IAI Co., Ltd. can be used for the lift.

This allows attachment or detachment of the probe unit, the charge/discharge power supply unit, the charge/discharge power supply-integrated probe unit, and the like to or from battery inspection units provided with no lifting mechanism, stockers used as dedicated shelves (storage shelves) for probe units or power supply units, and the like.

In other words, since there is no need to provide a dedicated lifting mechanism to battery inspection units provided with no lifting mechanism and the like, it is possible to reduce the cost for providing a lifting mechanism, the cost for maintenance (repair or replacement) of the lifting mechanism, and the like.

### Operational Flow in Charge/Discharge Inspection System

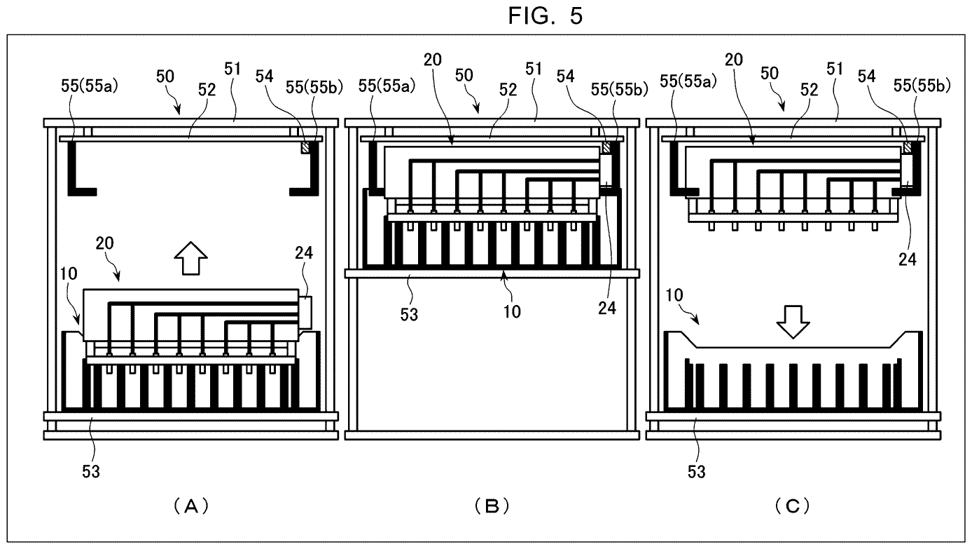

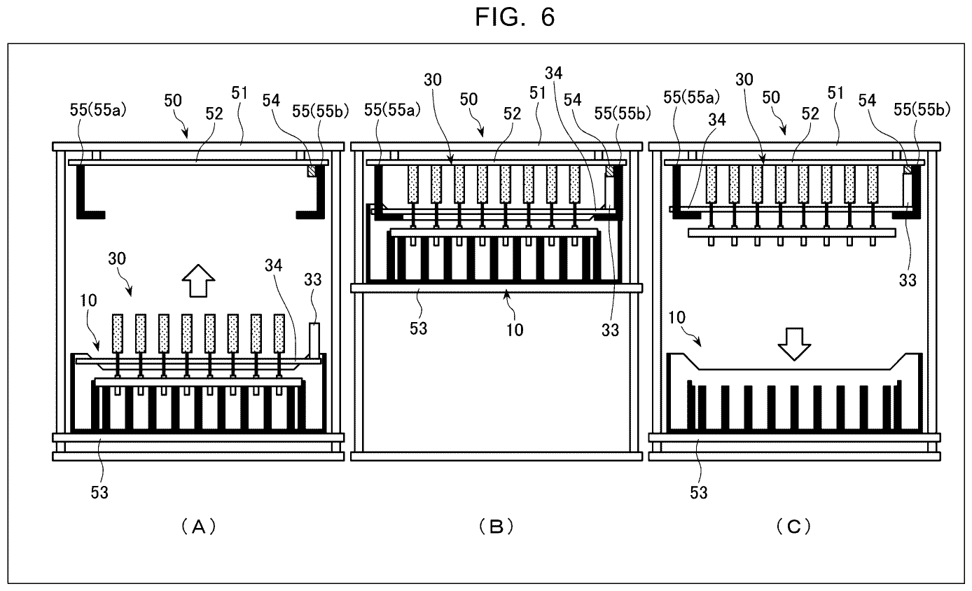

Next, an operational flow in the charge/discharge inspection system according to this embodiment will be described with reference to FIGS. 5 and 6.

### Probe Unit

FIG. 5 is a diagram illustrating a flow in which the tray 10 conveys the probe unit 20 to a battery inspection unit 50. In this embodiment, the battery inspection unit 50 has a hanging plate 52 that is hung on a top plate 51, and the hanging plate 52 is provided with a battery inspection unit-side connecting part 54 and probe unit fixing mechanisms 55. Further, the battery inspection unit 50 has a lifting plate 53 on which the tray 10 is placed and that rises or lowers via a lifting mechanism (not shown).

First, suppose that the battery inspection unit 50 is in the state where the probe unit is not connected thereto due to, for example, cleaning of the tips of the probes or replacement (removal) of defective probes.

Since the tray 10 can contain the probe unit 20 as mentioned above (see FIG. 2), a cleaned probe unit or a new probe unit is contained in the tray 10, and then conveyed to the battery inspection unit 50 of the charge/discharge inspection apparatus by a conveying apparatus such as a stacker crane or an automatic guided vehicle (AGV).

Further, when the tray 10 is conveyed to the battery inspection unit 50, it is placed on the lifting plate 53 of the battery inspection unit 50 using a known method such as forking and push-pull (see FIG. 5 (A)).

After that, the lifting mechanism lifts the lifting plate 53 with the tray 10 placed thereon. Note that since the placed tray 10 is also lifted with the conveyed probe unit 20 contained therein, the lifting plate 53 is lifted by the lifting mechanism until the connecting part 24 of the probe unit 20 is connected to the battery inspection unit-side connecting part 54 of the battery inspection unit 50 (see FIG. 5(B)).

When the probe unit 20 (the tray 10) is lifted until the connecting part 24 of the probe unit 20 is connected to the battery inspection unit-side connecting part 54 of the battery inspection unit 50, the probe unit 20 is fixed to the battery inspection unit 50 by the probe unit fixing mechanisms 55 of the battery inspection unit 50.

Although this embodiment assumes that the probe unit fixing mechanisms 55 are fixing mechanisms (55a and 55b) provided at both ends (the left and right ends) of the hanging plate 52 and are mechanisms that fix the probe unit 20 from the left and right to support it at an upper position in the battery inspection unit 50, the present invention is not limited thereto as long as the probe unit 20 can be fixed to a specific position.

Then, the lifting mechanism lowers the lifting plate 53 to separate the tray 10 from the probe unit 20 (see FIG. 5 (C)). The tray 10 placed on the lifting plate 53 is transferred to the conveying apparatus again using a known method such as forking or push-pull and conveyed to a predetermined location.

### Charge/Discharge Power Supply-Integrated Probe Unit

On the other hand, FIG. 6 is a diagram illustrating a flow in which the tray 10 conveys the charge/discharge power supply-integrated probe unit 30 to the battery inspection unit 50. Note that when the charge/discharge power supply-integrated probe unit 30 is connected, the battery inspection unit-side connecting part 54 of the battery inspection unit 50 is configured to be connected to the charge/discharge power supply-integrated probe unit.

First, as in the case of the probe unit, suppose that the battery inspection unit 50 is in the state where the charge/discharge power supply-integrated probe unit is not connected thereto due to cleaning of the tips of the probes or replacement (removal) of defective probes.

Since the tray 10 can contain the charge/discharge power supply-integrated probe unit 30 (see FIG. 3), a cleaned one or a new one is contained in the tray 10, and then conveyed to the battery inspection unit 50 by the conveying apparatus.

Further, when the tray 10 is conveyed to the battery inspection unit 50, it is placed on the lifting plate 53 of the battery inspection unit 50 (see FIG. 6 (A)).

After that, the lifting plate 53 is lifted by the lifting mechanism until the connecting part 33 of the charge/discharge power supply-integrated probe unit 30 is connected to the battery inspection unit-side connecting part 54 of the battery inspection unit 50 by the lifting mechanism (see FIG. 6 (B)).

When the connecting part 33 of the charge/discharge power supply-integrated probe unit 30 is connected to the battery inspection unit-side connecting part 54 of the battery inspection unit 50, the charge/discharge power supply-integrated probe unit 30 is fixed to the battery inspection unit 50 by the probe unit fixing mechanisms 55 of the battery inspection unit 50. Although the probe unit fixing mechanisms 55 in this embodiment are configured to fix the charge/discharge power supply-integrated probe unit 30 by engaging with its casing (outer frame) 34, the present invention is not limited thereto as long as the charge/discharge power supply-integrated probe unit 30 can be fixed to a specific position.

Then, the lifting mechanism lowers the lifting plate 53 to separate the tray 10 from the charge/discharge power supply-integrated probe unit 30 (see FIG. 6 (C)). The tray 10 placed on the lifting plate 53 is transferred to the conveying apparatus and used for the next work.

Of course, contrary to conveying and connecting the probe unit 20 or the power supply-integrated probe unit 30 to the battery inspection unit 50 as described with reference to FIGS. 5 and 6, the probe unit 20 or the power supply-integrated probe unit 30 connected to the battery inspection unit 50 can also be removed, contained in the tray 10, and conveyed from the battery inspection unit 50 to another location.

For example, when the object to be conveyed by the tray 10 is the probe unit 20, the tray 10 that contains nothing is placed on the lifting plate 53 (see FIG. 5 (C)). Then, the lifting plate 53 is lifted by the lifting mechanism and the probe unit 20 is contained in the tray 10 (see FIG. 5(B)). Thereafter, the connecting part 24 is disconnected from the battery inspection unit-side connecting part 54 (the probe unit is removed from the battery inspection unit), the lifting plate 53 is lowered by the lifting mechanism, and the tray 10 containing the probe unit 20 is conveyed to another location (see FIG. 5(A)).

In this way, although replacement of the probe unit of the battery inspection unit or the like requires a mechanism for removing the probe unit from the battery inspection unit separately from the conveying tray for conveying the probe unit, the charge/discharge inspection system according to the present invention can only use the tray 10 to remove the probe unit from the battery inspection unit or connect the probe unit to the battery inspection unit.

Further, although the lifting mechanism in the embodiment shown in FIGS. 5 and 6 is configured to lift or lower the lifting plate 53, it may also be configured to lift or lower the hanging plate 52 of the battery inspection unit 50 instead of the lifting plate 53. In this case, for example, taking the probe unit 20 shown in FIG. 5 as an example, the hanging plate 52 is lowered by the lifting mechanism until the battery inspection unit-side connecting part 54 is connected to the connecting part 24 of the probe unit 20 contained in the tray 10 placed on the lifting plate 53.

Note that although the embodiment shown in FIGS. 5 and 6 takes the probe unit 20 and the power supply-integrated probe unit 30 as examples, it is also possible to lift or lower the lifting plate 53 or the hanging plate 52 via the lifting mechanism to connect the charge/discharge power supply unit 32 including the connecting part 33 to the battery inspection unit-side connecting part 54.

### Fixing Mechanism

To improve safety in such an operational flow, the charge/discharge inspection system desirably includes fixing mechanisms.

### Tray-Side Fixing Mechanism

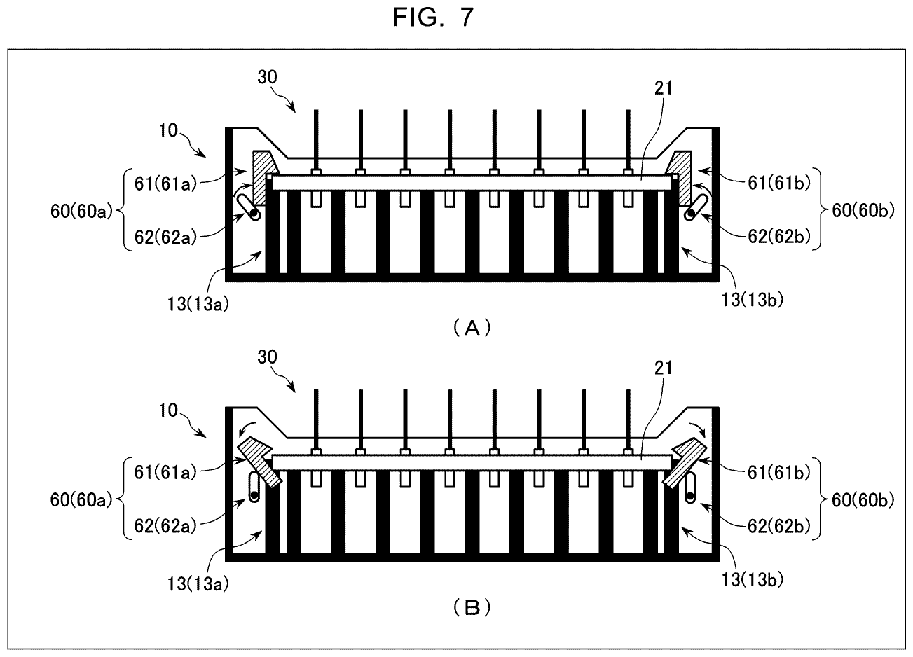

FIG. 7 is a diagram illustrating an example of tray-side fixing mechanisms 60. In this embodiment, the tray-side fixing mechanisms 60 (60a and 60b) are provided to the tray 10 (the guide parts 13a and 13b, respectively), and include locking parts 61 (61a and 61b) and operating parts 62 (62a and 62b).

As shown in FIG. 7 (A), at the time of locking, the locking parts 61 (61a and 61b) engage with the probe holding plate 21 of the charge/discharge power supply-integrated probe unit 30, and thus the charge/discharge power supply-integrated probe unit 30 is fixed to the tray 10. The probe unit 20 can also be fixed in the same way.

This allows the probe unit 20 or the charge/discharge power supply-integrated probe unit 30 contained in the storage part 11 of the tray 10 to be firmly fixed to the tray 10 when the tray 10 is conveyed by the conveying apparatus, or when the tray 10 rises or lowers while being placed on the lifting plate 53 of the battery inspection unit 50.

Note that at the time of unlocking, the locking parts 61 (61a and 61b) can be disengaged by the operating parts 62 (62a and 62b) as shown in FIG. 7 (B). For example, the operating parts 62 (62a and 62b) rotate about pivots (see the arrows shown in FIG. 7(A)) to apply force to portions of the locking parts 61 (61a and 61b), thereby enabling separation of portions where the probe holding plate 21 engages with the locking parts 61 (61a and 61b) (see the arrows shown in FIG. 7(B)).

Although the tray-side fixing mechanisms 60 in this embodiment include the locking parts 61 and the operating parts 62, known techniques, such as an auto-latch that engages one member with another member, a pin unit, and an anti-back unit, can be used as such fixing mechanisms on the tray 10 side or on the battery inspection unit 50 side.

Further, the tray-side fixing mechanisms 60 can fix the probe unit 20 to the tray 10 by engaging the locking parts 61 with the probe holding plate 21 of the probe unit 20 in the same way.

Note that the tray-side fixing mechanism 60 can also fix the charge/discharge power supply unit 32 to the tray 10. In this case, instead of the probe holding plate 21, the charge/discharge power supply unit 32 has only to have parts with which the locking parts 61 of the tray-side fixing mechanism 60 can firmly engage, such as its casing (outer frame).

Of course, it is also possible to engage the locking parts 61 of the tray-side fixing mechanism 60 with other parts of the probe unit 20 or the charge/discharge power supply-integrated probe unit 30 than the probe holding plate 21.

### Battery Inspection Unit-Side Fixing Mechanism

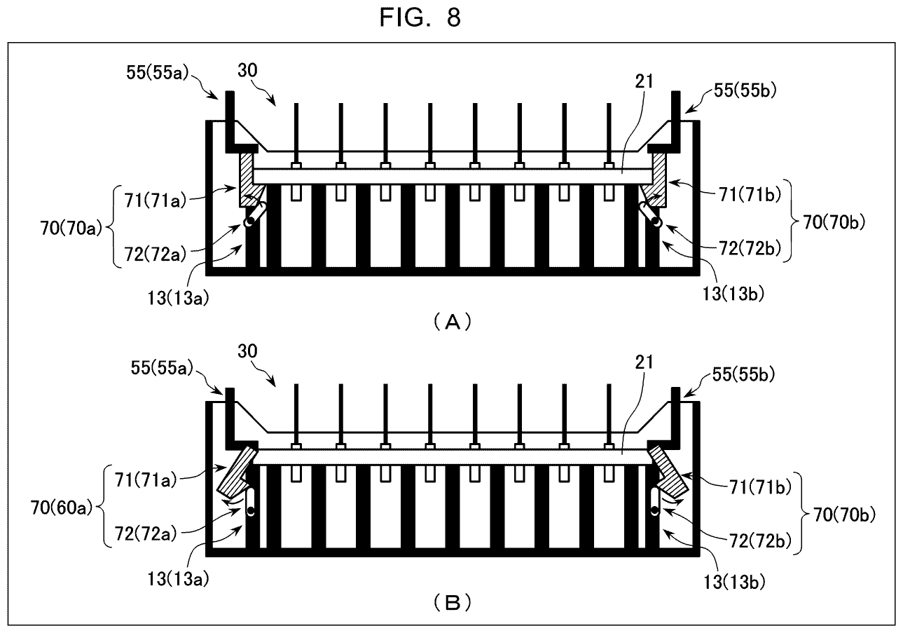

On the other hand, FIG. 8 is a diagram illustrating an example of battery inspection unit-side fixing mechanisms 70. In this embodiment, the battery inspection unit-side fixing mechanisms 70 (70a and 70b) are provided over the battery inspection unit 50 side (the probe unit fixing mechanisms 55a and 55b) and the tray 10 side, and include locking parts 71 (71a and 71b) and operating parts 72 (72a and 72b).

In this embodiment, as shown in FIG. 8 (A), at the time of locking, the locking parts 71 (71a and 71b) provided to the respective probe unit fixing mechanisms 55a and 55b engage with the probe holding plate 21 of the charge/discharge power supply-integrated probe unit 30, and thus the charge/discharge power supply-integrated probe unit 30 is fixed to the battery inspection unit 50. The probe unit 20 can also be fixed in the same way.

Note that, at the time of unlocking, the operating parts 72 (72a and 72b) provided to the tray 10 (the guide parts 13a and 13b, respectively) rotate about pivots (see the arrows shown in FIG. 8(A)) to apply force to portions of the locking parts 71 (71a and 71b), thereby enabling separation of portions where the probe holding plate 21 engages with the locking parts 71 (71a and 71b) (see the arrows shown in FIG. 8(B)).

Further, the battery inspection unit-side fixing mechanisms 70 can also fix the probe unit 20 or the charge/discharge power supply unit 32 to the battery inspection unit 50 as in the case of the tray-side fixing mechanisms 60. Further, parts that engage with the locking parts 71 of the battery inspection unit-side fixing mechanisms 70 are not limited to the probe holding plate 21. In addition, it is also possible to use a configuration in which the operating units 72 are provided on the battery inspection unit 50 side, and known techniques can be used as fixing mechanisms on the tray 10 side and on the battery inspection unit 50 side as in the case of the tray-side fixing mechanisms 60.

### Tray-Side Fixing Mechanism and Battery Inspection Unit-Side Fixing Mechanism

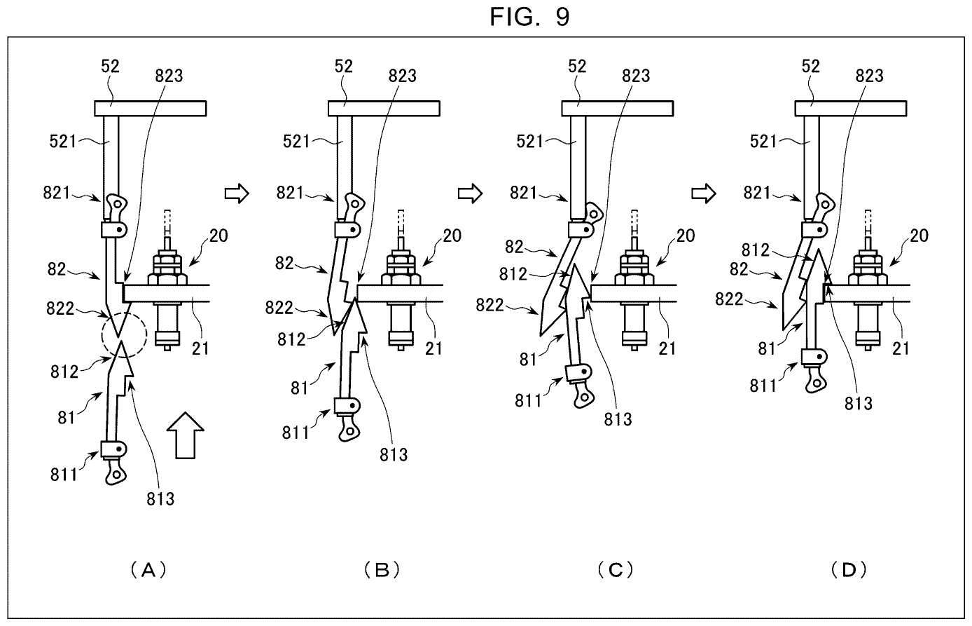

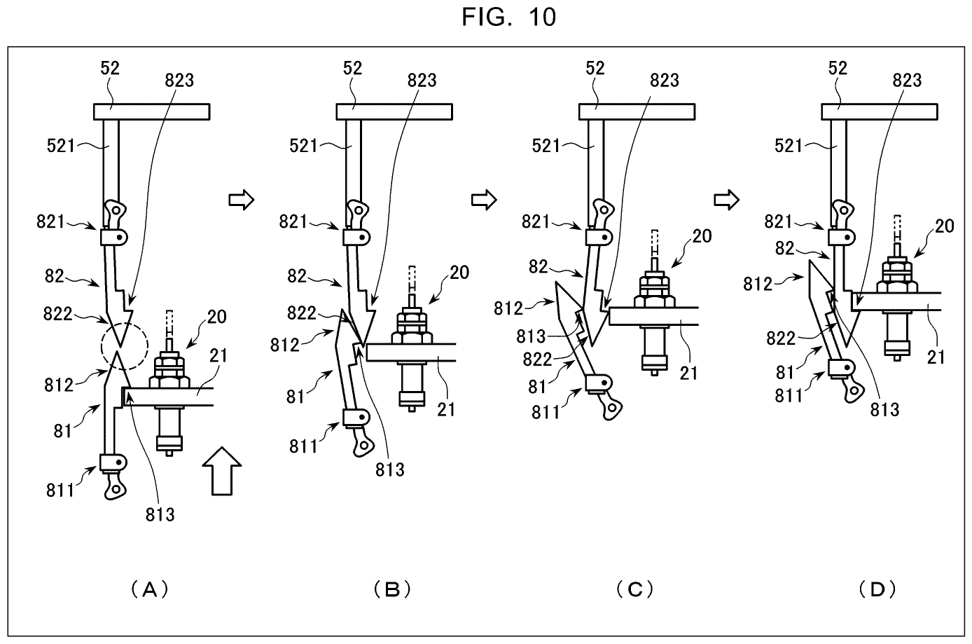

FIGS. 9 and 10 are diagrams illustrating an example of a tray-side fixing mechanism 81 and a battery inspection unit-side fixing mechanism 82 each composed only of a locking part. As shown in FIG. 9, the tray-side fixing mechanism 81 has a pivot part 811, and the pivot part 811 is, for example, movably attached to the tray 10.

Further, a tip part 812 of the tray-side fixing mechanism 81 is tapered, and an engaging part 813 in such a shape as to engage with the probe holding plate 21 is formed on a portion of the tip part 812.

On the other hand, the battery inspection unit-side fixing mechanism 82 consists of a pivot part 821, a tip part 822, and an engaging part 823 that have the same functions as those of the tray-side fixing mechanism 81. In the battery inspection unit-side fixing mechanism 82, for example, the pivot part 821 is movably attached to a support member 521 extending from the hanging plate 52.

To describe operation of them with reference to FIG. 9, FIG. 9 is a diagram illustrating a procedure in which the probe unit (the probe holding plate 21), which is initially fixed by the battery inspection unit-side fixing mechanism 82, is next fixed to the tray by the tray-side fixing mechanism 81.

Here, the tip part of the mechanism on the side on which the probe unit is fixed next (which is, in the example shown in FIG. 9, the tip part 812 of the tray-side fixing mechanism 81) is positioned on the inner side (on the probe holding plate 21 side) than the tip part of the mechanism on the side on which it is initially fixed (which is, in the example shown in FIG. 9, the tip part 822 of the battery inspection unit-side fixing mechanism 82) (see the dashed frame in FIG. 9 (A)).

By lifting the tray-side fixing mechanism 81 from this state, the tip part 812 of the tray-side fixing mechanism 81 hits the inside of the tip part 822 of the battery inspection unit-side fixing mechanism 82 (see FIG. 9 (B)), and rises as it is while pushing the tip part 822 of the battery inspection unit-side fixing mechanism 82 outward (see FIG. 9 (C)).

Then, by lifting the tray-side fixing mechanism 81 until the engaging part 813 of the tray-side fixing mechanism 81 engages with the probe holding plate 21, the fixation by the battery inspection unit-side fixing mechanism 82 is released, and the probe unit is fixed to the tray by the tray-side fixing mechanism 81 (see FIG. 9 (D)).

Further, FIG. 10 is a diagram illustrating a procedure in which the probe unit (the probe holding plate 21), which is initially fixed by the tray-side fixing mechanism 81, is next fixed in the battery inspection unit by the battery inspection unit-side fixing mechanism 82.

In this case, the tip part of the mechanism on the side on which the probe unit is fixed next (which is, in the example shown in FIG. 10, the tip part 822 of the battery inspection unit-side fixing mechanism 82) is located inside the tip part of the mechanism on the side on which it is initially fixed (which is, in the example shown in FIG. 10, the tip part 812 of the tray-side fixing mechanism 81) (see the dashed frame in FIG. 10 (A)).

By lifting the tray from this state, the tray-side fixing mechanism 81 and the probe unit contained in the tray rise, the tip part 822 of the battery inspection unit-side fixing mechanism 82 hits the inside of the tip part 812 of the tray-side fixing mechanism 81 (see FIG. 10 (B)), and the tip part 812 of the tray-side fixing mechanism 81 rises as it is while being pushed outward (see FIG. 10 (C)).

Then, by lifting the tray (the probe unit contained in the tray) until the engaging part 823 of the battery inspection unit-side fixing mechanism 82 engages with the probe holding plate 21, the fixation by the tray-side fixing mechanism 81 is released, and the probe unit is fixed in the battery inspection unit by the battery inspection unit-side fixing mechanism 82 (see FIG. 10 (D)).

Here, although not shown, a plurality of tray-side fixing mechanisms 81 and a plurality of battery inspection unit-side fixing mechanisms 82 are provided as in the case of the tray-side fixing mechanisms 60a and 60b and the battery inspection unit-side fixing mechanisms 70a and 70b. Further, the places where they are provided are not limited, and the part that engages with the engaging part 813 of the tray-side fixing mechanism 81 or the engaging part 823 of the battery inspection unit-side fixing mechanism 82 is not limited to the probe holding plate 21.

Note that the above-described positional relationship between the tip part 812 of the tray-side fixing mechanism 81 and the tip part 822 of the battery inspection unit-side fixing mechanism 82 can be adjusted based on the position where the tray 10 is placed on the lifting plate 53 or the like (see FIGS. 5 and 6).

### Maintenance Station

The tray 10 that contains the probe unit 20 or the power supply-integrated probe unit 30 removed from the battery inspection unit 50 can be conveyed to the maintenance station. The maintenance station is a facility in which the probes 22 of the conveyed probe unit 20 can be cleaned or replaced. Further, the maintenance station is a facility that allows, for example, automatic calibration or replacement of the power supplies 31 of the conveyed power supply-integrated probe unit 30.

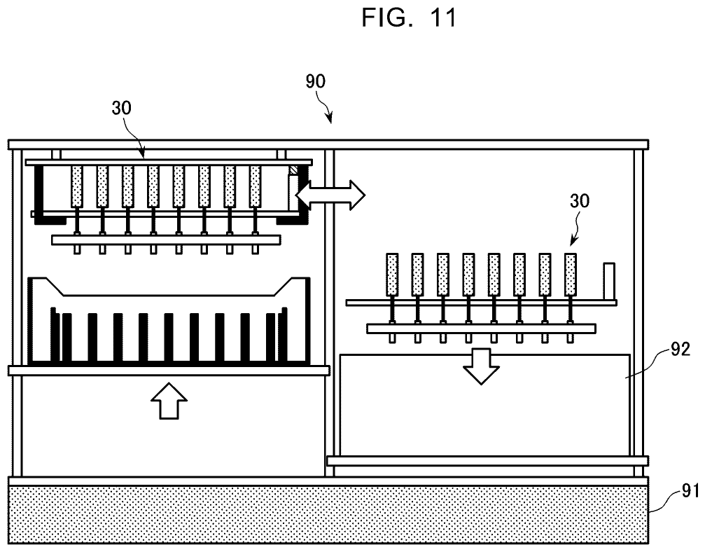

At this time, for example, the power supply-integrated probe unit 30 conveyed into the maintenance station 90 together with the tray 10 is lifted by the lifting mechanism together with the tray 10, then only the power supply-integrated probe unit 30 is held, slid, and connected to a calibration jig 92 placed on a calibrator mounting base 91, thereby enabling automatic calibration of the power supplies 31 (see FIG. 11).

In this way, since the charge/discharge inspection system according to the present invention can easily convey the probe unit 20 or the like to the maintenance station 90 using the tray 10, it is possible to easily perform maintenance that takes time and effort and requires safety such as cleaning or replacing the probes 22.

The charge/discharge inspection system described above illustrates the charge/discharge inspection system of the present invention as an example, and the configuration of the present invention is not limited to the illustrated one unless it deviates from the spirit of the present invention.

For example, the design of the components such as the tray separators 12 and the guide parts 13 provided in the tray 10 can be modified appropriately according to the type or size of the probe unit 20, the charge/discharge power supply unit 32, or the charge/discharge power supply-integrated probe unit 30 that is to be contained, or the secondary batteries 40 to be inspected, or the like.

### Industrial Applicability

The present invention is useful in industry because it can be used in various situations as a charge/discharge inspection system that enables easy maintenance such as cleaning the tips of probes, replacing defective probes, and calibrating power supplies without a complex configuration.

### Reference Signs List

10 tray
11 storage part
12 tray separator
13, 13a, 13b, 13c guide part
13T, 13Ta, 13Tb, 13Tc top of guide part
20 probe unit
21 probe holding plate
22 probe
23 wire
24 probe unit-side connecting part
25 electrical component storage
30 power supply-integrated probe unit
31 power supply
32 charge/discharge power supply unit
33 power supply-integrated probe unit-side connecting part
34 casing (outer frame)
40 secondary battery
50 battery inspection unit
51 top plate
52 hanging plate
521 support member for hanging plate
53 lifting plate
54 battery inspection unit-side connecting part
55, 55a, 55b probe unit fixing mechanism
60, 60a, 60b tray-side fixing mechanism
61, 61a, 61b locking part of tray-side fixing mechanism
62, 62a, 62b operating part of tray-side fixing mechanism
70, 70a, 70b battery inspection unit-side fixing mechanism
71, 71a, 71b locking part of battery inspection unit-side fixing mechanism
72, 72a, 72b operating part of battery inspection unit-side fixing mechanism
81 tray-side fixing mechanism
811 pivot part of tray-side fixing mechanism
812 tip part of tray-side fixing mechanism
813 engaging part of tray-side fixing mechanism
82 battery inspection unit-side fixing mechanism
821 pivot part of battery inspection unit-side fixing mechanism
822 tip part of battery inspection unit-side fixing mechanism
823 engaging part of battery inspection unit-side fixing mechanism
90 maintenance station
91 calibrator mounting base
92 calibration jig

1. A charge/discharge inspection system comprising:
a battery inspection unit of a charge/discharge inspection apparatus;
a tray that has a storage part, is capable of containing a probe unit, a charge/discharge power supply unit, and a charge/discharge power supply-integrated probe unit in the storage part from above, is conveyed with one of the probe unit, the charge/discharge power supply unit, and the charge/discharge power supply-integrated probe unit contained in the tray, and is placed in the battery inspection unit; and
a conveying apparatus that conveys the tray from the battery inspection unit to another location, or conveys the tray from another location to the battery inspection unit.

2. The charge/discharge inspection system according to claim 1, wherein the tray comprises:
a plurality of tray separators that separate a storage area in the storage part; and
a guide part that supports the probe unit or the charge/discharge power supply-integrated probe unit contained in the storage part so that a probe of the probe unit or the charge/discharge power supply-integrated probe unit does not contact with an inside of the storage part.

3. The charge/discharge inspection system according to claim 2, wherein
the storage part is capable of further containing a secondary battery to be inspected, and
the tray is conveyed with the secondary battery to be inspected contained in the tray, and is placed in the battery inspection unit.

4. The charge/discharge inspection system according to claim 1, wherein the storage part is capable of further containing a lift capable of lifting or lowering the probe unit, the charge/discharge power supply unit, or the charge/discharge power supply-integrated probe unit.

5. The charge/discharge inspection system according to claim 1, wherein the tray comprises a tray-side fixing mechanism for fixing, to the tray, the probe unit, the charge/discharge power supply unit, or the charge/discharge power supply-integrated probe unit contained in the storage part of the tray when the tray is conveyed by the conveying apparatus, when the tray rises or lowers while being placed on a lifting plate of the battery inspection unit, or when the probe unit, the charge/discharge power supply unit, or the charge/discharge power supply-integrated probe unit is contained in the tray.

6. The charge/discharge inspection system according to claim 5, wherein the battery inspection unit comprises a battery inspection unit-side fixing mechanism for fixing, in the battery inspection unit, the probe unit, the charge/discharge power supply unit, or the charge/discharge power supply-integrated probe unit that is conveyed while being contained in the tray.

7. The charge/discharge inspection system according to claim 1, comprising:
a lifting mechanism that lifts the tray placed on a lifting plate of the battery inspection unit, and connects the probe unit, the charge/discharge power supply unit, or the charge/discharge power supply-integrated probe unit contained in the tray and a connecting part provided on the battery inspection unit side to each other; or
a lifting mechanism that lowers a hanging plate of the battery inspection unit, and connects the probe unit, the charge/discharge power supply unit, or the charge/discharge power supply-integrated probe unit contained in the tray placed in the battery inspection unit and the connecting part provided on the battery inspection unit side to each other.
